(19) United States
(12) Patent Application Publication
(10) Pub. No.: US 2014/0144380 A1
(43) Pub. Date: May 29, 2014

(54) GAS SUPPLY PIPES AND CHEMICAL VAPOR DEPOSITION APPARATUS

(71) Applicant: SAMSUNG ELECTRONICS CO., LTD., Suwon-si (KR)

(72) Inventors: Sung-ho Kang, Osan-si (KR); Bong-jin Kuh, Suwon-si (KR); Ki-chul Kim, Seongnam-si (KR); Jin-kwon Bok, Suwon-si (KR); Yong-kyu Joo, Hwaseong-si (KR); Sang-cheol Ha, Suwon-si (KR)

(21) Appl. No.: 13/687,642

(22) Filed: Nov. 28, 2012

(51) Int. Cl. C23C 16/455

(52) U.S. Cl. CPC C23C 16/455
USPC 118/712; 137/334

(57) ABSTRACT

A gas supply pipe and a chemical vapor deposition (CVD) apparatus including the gas supply pipe. The gas supply pipe includes: a first pipe connected to a gas storage apparatus via a gas supply line to supply a reacting gas into a reacting furnace; and a second pipe thermally contacting the first pipe to cool the first pipe, wherein a first end of the second pipe is connected to a cooling medium supplying unit via a cooling medium line such that a cooling medium circulates inside the second pipe, and a second, opposite end of the second pipe is connected to a cooling medium collecting unit.

### REFERENCE TO PRIORITY APPLICATION

This application claims the benefit of Korean Patent Application No. 10-2012-0013327, filed on Feb. 9, 2012, the disclosure of which is hereby incorporated by reference herein in its entirety.

### FIELD

The inventive concept relates to a gas supply pipe and a chemical vapor deposition (CVD) apparatus including the same, and more particularly, to a gas supply pipe for supplying a reacting gas into a reacting furnace and a CVD apparatus including the gas supply pipe.

### BACKGROUND

Semiconductor wafers may be processed through various processes by using various apparatuses such as a photo apparatus, a stepper apparatus, a sawing apparatus, or a CVD apparatus. A CVD apparatus may include a gas supply pipe for supplying a reacting gas into a reacting furnace. Especially at high temperatures, reacting gas may form deposits in gas supply pipes, including those used with CVD apparatus.

### SUMMARY

According to an aspect of the inventive concept, a gas supply pipe includes: a first pipe connected to a gas storage apparatus via a gas supply line to supply a reacting gas into a reacting furnace; and a second pipe thermally contacting the first pipe to cool the first pipe. A first end of the second pipe is connected to a cooling medium supplying unit via a cooling medium line such that a cooling medium circulates inside the second pipe, and a second, opposite end of the second pipe is connected to a cooling medium collecting unit.

The first pipe may be a cylindrical pipe in which a plurality of gas outlets are disposed at a front side of the first pipe. An upper end of the first pipe may be closed.

The second pipe may be installed outside of the first pipe and extend along diametrically opposed first and second side surfaces of the first pipe. In some embodiments, the second pipe extends from the cooling medium supplying unit along the first side surface of the first pipe, an upper end of the first pipe, and the second side surface of the first pipe to the cooling medium collecting unit.

The second pipe may be formed to have a crescent-shaped cross-section to closely contact the first pipe.

The second pipe may be installed inside of the first pipe.

The second pipe may be wound in a helical shape along an outer surface of the first pipe to pass between gas outlets of the first pipe.

The second pipe may be wound in a helical shape along an inner surface of the first pipe to pass between gas outlets of the first pipe.

The cooling medium may include at least one selected from the group consisting of helium (He) gas, argon (Ar) gas, nitride (N2) gas, inert gas, cooling water, and cooling oil, or a combination thereof.

According to another aspect of the inventive concept, a chemical vapor deposition (CVD) apparatus includes: a reacting furnace sized and configured to accommodate at least one wafer loaded on a boat; a gas supply pipe; a temperature sensor; and a controller. The gas supply pipe includes a first pipe connected to a gas storage apparatus via a gas supply line to supply a reacting gas into the reacting furnace, and a second pipe thermally contacting the first pipe to cool the first pipe, wherein a first end of the second pipe is connected to a cooling medium supplying unit via a cooling medium line such that a cooling medium circulates inside the second pipe, and a second, opposite end of the second pipe is connected to a cooling medium collecting unit. The temperature sensor is configured to measure a temperature of the first pipe The controller is configured to receive a temperature signal indicating a temperature from the temperature sensor and configured to apply a control signal to the cooling medium supplying unit and/or the cooling medium collecting unit responsive to the received temperature signal.

In some embodiments, the controller is configured to apply a cooling stop signal to the cooling medium supplying unit and/or the cooling medium collecting unit when the temperature signal indicates a temperature lower than a first temperature, and the controller is configured to apply a cooling operation signal to the cooling medium supplying unit and/or the cooling medium collecting unit when the temperature signal indicates a temperature greater than a second temperature. In some embodiments, the first temperature is about 400° C. In some embodiments, the second temperature is about 500° C.

According to another aspect of the inventive concept, a chemical vapor deposition (CVD) apparatus includes: a reacting furnace sized and configured to accommodate at least one wafer loaded on a boat; a gas supply pipe; a temperature sensor; and a controller. The gas supply pipe includes a first pipe connected to a gas storage apparatus via a gas supply line, the first pipe having a plurality of gas outlets to supply gas from the first pipe to the reacting furnace. The gas supply pipe also includes a second pipe thermally contacting the first pipe to cool the first pipe, wherein a first end of the second pipe is connected to a cooling medium supplying unit via a cooling medium line such that a cooling medium circulates inside the second pipe, and wherein a second, opposite end of the second pipe is connected to a cooling medium collecting unit. The temperature sensor is configured to measure a temperature of at least one of the first pipe and reacting gas within the first pipe. The controller is configured to receive a temperature signal indicating a temperature from the temperature sensor and configured to apply a control signal to at least one of the cooling medium supplying unit and the cooling medium collecting unit responsive to the received temperature signal.

It is noted that any one or more aspects or features described with respect to one embodiment may be incorporated in a different embodiment although not specifically described relative thereto. That is, all embodiments and/or features of any embodiment can be combined in any way and/or combination. Applicant reserves the right to change any originally filed claim or file any new claim accordingly, including the right to be able to amend any originally filed claim to depend from and/or incorporate any feature of any other claim although not originally claimed in that manner. These and other objects and/or aspects of the present invention are explained in detail in the specification set forth below.

### BRIEF DESCRIPTION OF THE DRAWINGS

Exemplary embodiments of the inventive concept will be more clearly understood from the following detailed description taken in conjunction with the accompanying drawings in which:

FIG. 1 is a schematic view showing a gas supply pipe and a CVD apparatus including the gas supply pipe according to embodiments of the inventive concept;

FIG. 2 is a partial perspective view showing the gas supply pipe of FIG. 1;

FIG. 3 is a cross-sectional side view showing the gas supply pipe of FIG. 2;

FIG. 4 is a cross-sectional view taken along line IV-IV of FIG. 2;

FIG. 5 is a cross-sectional view showing a gas supply pipe according to other embodiments of the inventive concept;

FIG. 6 is a cross-sectional view showing a gas supply pipe according to other embodiments of the inventive concept;

FIG. 7 is a partial perspective view showing a gas supply pipe according to other embodiments of the inventive concept;

FIG. 8 is a cross-sectional view taken along line VIII-VIII of FIG. 7; and

FIG. 9 is a cross-sectional view showing a gas supply pipe according to other embodiments of the inventive concept.

### DETAILED DESCRIPTION OF THE EMBODIMENTS

The present inventive concept will be described more fully with reference to the accompanying drawings.

The inventive concept may, however, be embodied in many different forms and should not be construed as limited to the exemplary embodiments set forth herein. Rather, these embodiments are provided so that this disclosure will be thorough and complete, and will fully convey the scope of the inventive concept to those skilled in the art. In the drawings, lengths and sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms ‘first’, ‘second’, ‘third’, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the inventive concept.

Spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Expressions such as “at least one of,” when preceding a list of elements, modify the entire list of elements and do not modify the individual elements of the list.

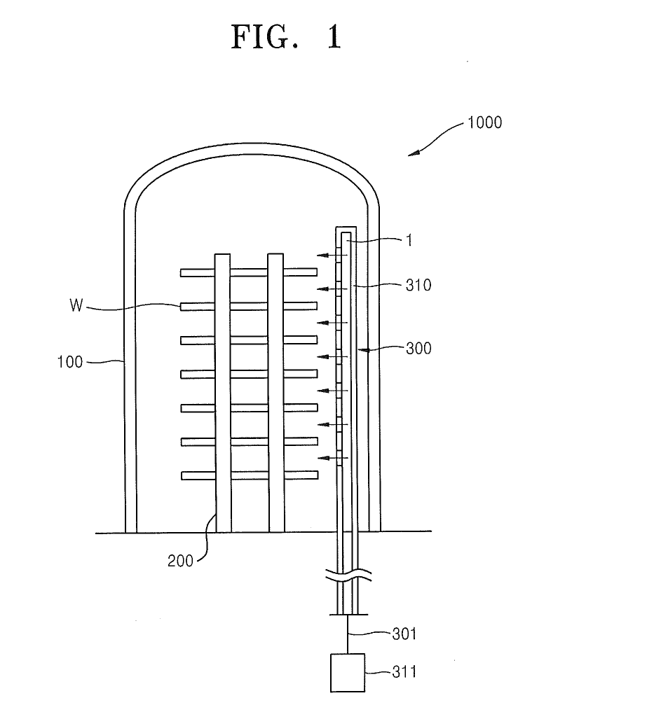

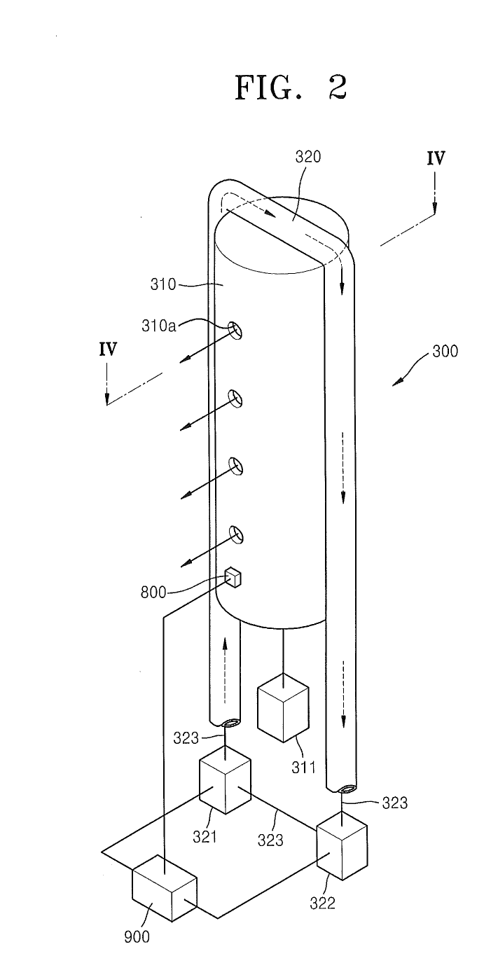

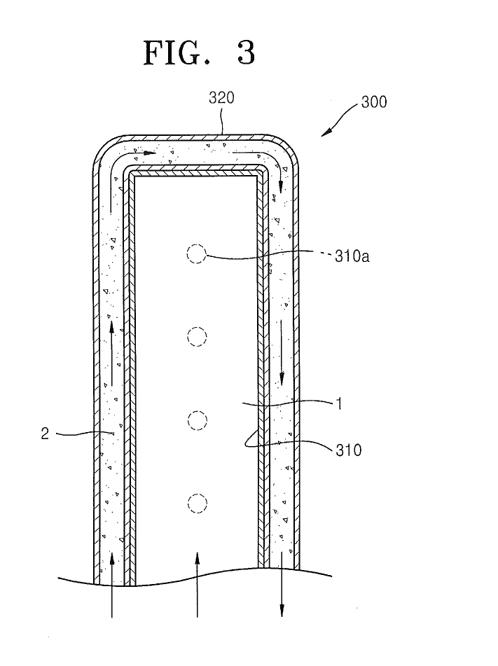

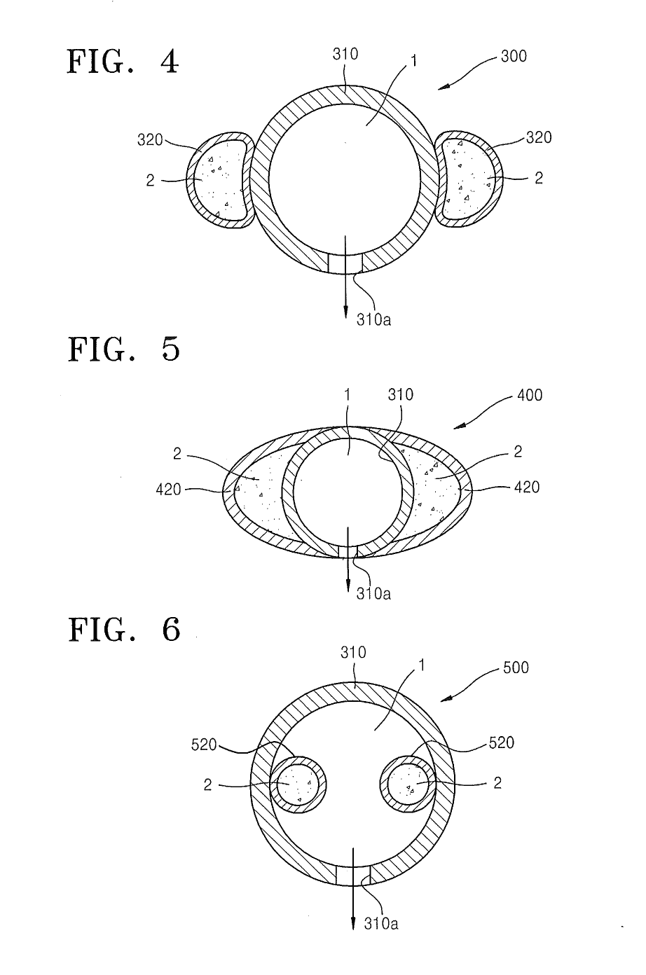

FIG. 1 is a schematic view showing a gas supply pipe 300 and a chemical vapor deposition (CVD) apparatus 1000 including the gas supply pipe 300 according to embodiments of the inventive concept. FIG. 2 is a partial perspective view showing the gas supply pipe 300 of FIG. 1. FIG. 3 is a cross-sectional side view showing the gas supply pipe 300 of FIG. 2. FIG. 4 is a cross-sectional view taken along line IV-IV of FIG. 2.

As shown in FIGS. 1 to 4, the gas supply pipe 300 according to the illustrated embodiments may include a first pipe 310 and a second pipe 320.

Here, the first pipe 310 is connected to a gas storage apparatus 311 via a gas supply line 301 to supply a reacting gas 1 to a reacting furnace 100. As shown in FIG. 2, the first pipe 310 may be a cylindrical pipe in which a plurality of gas outlets 310a are disposed at a front side of the first pipe 310 and an upper end thereof is closed.

Accordingly, as shown in FIG. 1, the reacting gas 1 may be stored in the gas storage apparatus 311, may be selectively emitted through the gas outlets 310a via the gas supply pipe 300, and may be supplied into the reacting furnace 100. Here, the gas outlets 310a may be installed at a lateral side or a rear side of the first pipe 310 instead of the front side of the first pipe 310, and the first pipe 310 may also be formed with a curved shape instead of a linear shape.

Also, as shown in FIGS. 2 and 3, the second pipe 320 has a heat contacting surface that contacts the first pipe 310 to cool the first pipe 310. One end of the second pipe 320 is connected to a cooling medium supplying unit 321 via a cooling medium line 323 so that a cooling medium 2 inside the second pipe 320 circulates, and the other end thereof is connected to a cooling medium collecting unit 322. As shown in FIG. 3, the second pipe 320 may be installed outside of the first pipe 310 by being bent in an inversed U-shape along left side, upper end, and right side portions of the first pipe 310. That is, the second pipe 320 may be installed outside the first pipe 310 and extend along diametrically opposed first and second side surfaces of the first pipe 310 (e.g., the left and right side portions). The second pipe 320 may extend from the cooling medium supplying unit 321 along the first side surface of the first pipe 310, the upper end of the first pipe 310, and the second side surface of the first pipe 310 to the cooling medium collecting unit 322.

Accordingly, when the first pipe 310 overheats inside the hot reacting furnace 100, the cooling medium 2 is circulated through the second pipe 320 by the cooling medium supplying unit 321 and then is collected in the cooling medium collecting unit 322 via the cooling medium line 323. At this time, the second pipe 320 may cool the first pipe 310 by performing heat exchange through a heat contacting portion.

As shown in FIG. 2, the cooling medium line 323 may be installed between the cooling medium supplying unit 321 and the cooling medium collecting unit 322 so as to circulate the cooling medium 2.

Also, the cooling medium 2 may be formed of at least one selected from the group consisting of helium (He) gas, argon (Ar) gas, nitride (N2) gas, inert gas, cooling water, and cooling oil, or a combination thereof. Here, the cooling medium 2 may use any of various other materials such as Freon gas or CO₂ gas in addition to the above-described gas.

As shown in FIG. 4, the second pipe 320 may be formed to have a crescent-shaped cross-section to closely contact the first pipe 310.

FIG. 5 is a cross-sectional view showing a gas supply pipe 400 according to other embodiments of the inventive concept.

As shown in FIG. 5, the second pipe 420 may be bent in a crescent shape to almost surround left and right side portions of the first pipe 310. In order to form the second pipe 420 in a crescent shape, the first pipe 310 may be bent in a crescent shape, and then a second pipe 420 may be formed at two sides of the first pipe 310 by welding or drawing. Alternatively, the first pipe 310 may be inserted into the second pipe 420 formed in a circular or oval shape by welding or drawing. Accordingly, as shown in FIG. 5, an area where heat exchange is performed, that is, a contact area between the first pipe 310 and the second pipe 420, may be increased.

FIG. 6 is a cross-sectional view showing a gas supply pipe 500 according to other embodiments of the inventive concept. As shown in FIG. 6, a second pipe 520 may be installed inside of the first pipe 310. Thus, an area where heat exchange is performed may be the entire surface of the second pipe 520, accordingly increasing a contact area between the first pipe 310 and the second pipe 520.

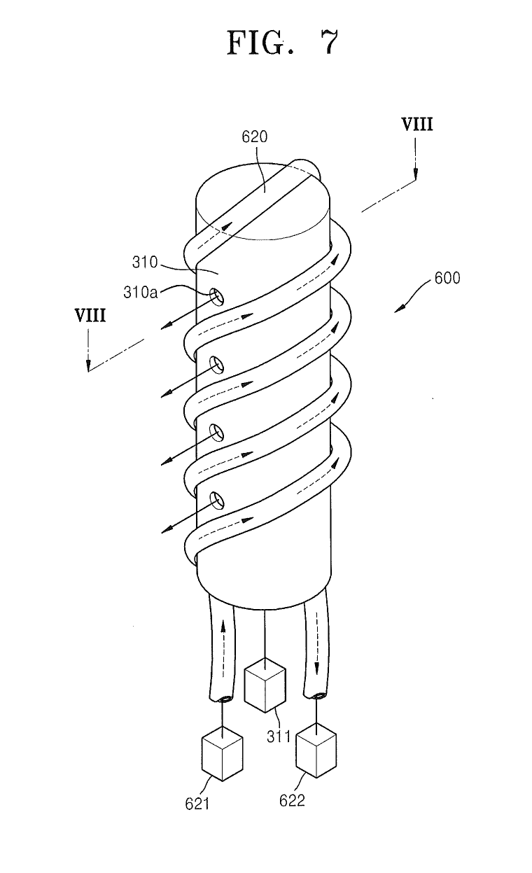

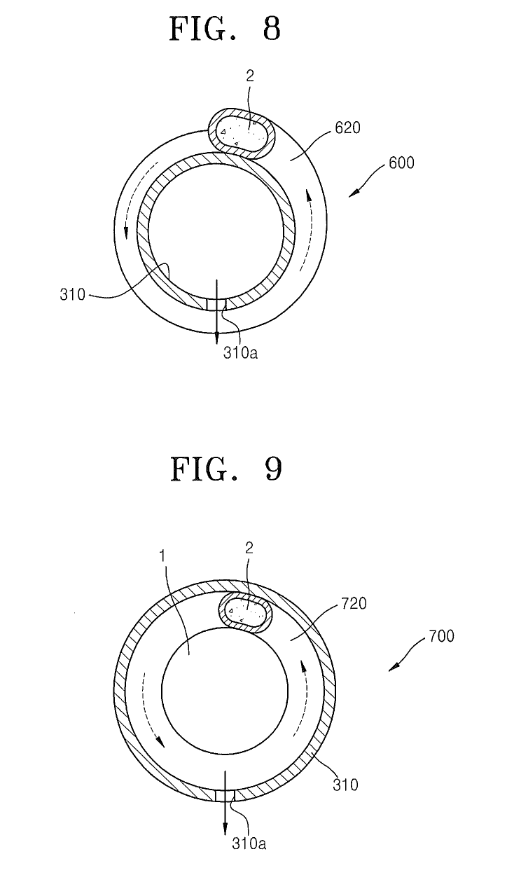

FIG. 7 is a partial perspective view showing a gas supply pipe 600 according to other embodiments of the inventive concept. FIG. 8 is a cross-sectional view taken along line VIII-VIII of FIG. 7.

As shown in FIGS. 7 and 8, a second pipe 620 may be wound in a helical shape along an outer surface of the first pipe 310 between the gas outlets 310a of the first pipe 310. In FIG. 7, although only a single segment of the second pipe 620 is formed to pass between two gas outlets 310a, the number of windings of the second pipe 620 and a winding position of the second pipe 620 may be modified without departing from the spirit and scope of the inventive concept. In other words, the second pipe 620 may be formed such that a plurality of segments of the second pipe 620 may pass between two gas outlets 310a, or alternatively, only a single segment of the second pipe 620 may pass between two of the gas outlets 310a.

Accordingly, as shown in FIGS. 7 and 8, an area where heat exchange is performed by winding the second pipe 620 in a helical shape along the outer surface of the first pipe 310, that is, a contact area between the first pipe 310 and the second pipe 620, may be increased.

FIG. 9 is a cross-sectional view showing a gas supply pipe 700 according to other embodiments of the inventive concept.

As shown in FIG. 9, a second pipe 720 may be installed in a helical shape inside of the first pipe 310 to pass between the gas outlets 310a of the first pipe 310.

Accordingly, as shown in FIG. 9, an area where heat exchange is performed by winding the second pipe 720 in a helical shape along an inner surface of the first pipe 310, that is, a contact area between the first pipe 310 and the second pipe 720, may be increased.

Further, as shown in FIGS. 1 and 2, the CVD apparatus 1000 including the above-described gas supply pipe 300 may include the reacting furnace 100, the gas supply pipe 300, a temperature sensor 800, and a controller 900.

Here, the reacting furnace 100 may be a hot reacting chamber accommodating at least one wafer W loaded on a boat 200, and the wafer W may be a semiconductor wafer or a reacting object having any of various shapes.

Also, the gas supply pipe 300 may include the first pipe 310, which is connected to the gas storage apparatus 311 via the gas supply line 301 to supply the reacting gas 1 to the reacting furnace 100. The gas supply pipe 300 may also include the second pipe 320 in which one end is connected to the cooling medium supplying unit 321 via the cooling medium line 323 so that the cooling medium 2 inside the second pipe 320 circulates and the other end is connected to the cooling medium collecting unit 322.

Also, as shown in FIG. 2, the temperature sensor 800 is a sensor that may measure a temperature of the first pipe 310, or may measure a temperature of the reacting gas 1 instead of the temperature of the first pipe 310.

As shown in FIG. 2, the controller 900 may be configured to receive a temperature signal indicating a temperature from the temperature sensor 800 and may be configured to apply a control signal to the cooling medium supplying unit 321 and/or the cooling medium collecting unit 322 responsive to the received temperature signal.

The controller 900 may apply a cooling stop signal to the cooling medium supplying unit 321 and/or the cooling medium collecting unit 322 when the temperature signal indicates a temperature that is less than or equal to a first temperature. The controller 900 may apply a cooling operation or start signal to the cooling medium supplying unit 321 and/or the cooling medium collecting unit 322 when the temperature signal indicates a temperature that is greater than or equal to a second temperature. According to some embodiments, the first temperature is about 400° C. and the second temperature is about 500° C.

Accordingly, the action of the controller 900 may inhibit or prevent the reacting gas 1 from being supplied at an excessively low temperature, and may prevent the reacting gas 1 from being supplied in an excessively high temperature and thus deposited inside of the first pipe 310.

A gas supply pipe according to the inventive concept and a CVD apparatus including the gas supply pipe can improve uniformity of gas emission by preventing a reacting gas from being deposited inside of a pipe, can improve durability of elements by allowing a gas to be smoothly supplied, can reduce an amount of a reacting gas supplied, and can greatly improve productivity, for example, an increase in a thickness of a reacting film deposited on a wafer or an increase in dispersion of deposition of the reacting film.

While the inventive concept has been particularly shown and described with reference to exemplary embodiments thereof, it will be understood that various changes in form and details may be made therein without departing from the spirit and scope of the following claims.

That which is claimed is:

1. A gas supply pipe comprising:
a first pipe connected to a gas storage apparatus via a gas supply line to supply a reacting gas into a reacting furnace; and
a second pipe thermally contacting the first pipe to cool the first pipe, wherein a first end of the second pipe is connected to a cooling medium supplying unit via a cooling medium line such that a cooling medium circulates inside the second pipe, and a second, opposite end of the second pipe is connected to a cooling medium collecting unit.

2. The gas supply pipe of claim 1, wherein the first pipe is a cylindrical pipe in which a plurality of gas outlets are disposed at a front side of the first pipe, and wherein an upper end of the first pipe is closed.

3. The gas supply pipe of claim 1, wherein the second pipe is installed outside of the first pipe and extends along diametrically opposed first and second side surfaces of the first pipe.

4. The gas supply pipe of claim 3, wherein the second pipe extends from the cooling medium supplying unit along the first side surface of the first pipe, an upper end surface of the first pipe, and the second side surface of the first pipe to the cooling medium collecting unit.

5. The gas supply pipe of claim 1, wherein the second pipe is formed to have a crescent-shaped cross-section to closely contact the first pipe.

6. The gas supply pipe of claim 1, wherein the second pipe is installed inside of the first pipe.

7. The gas supply pipe of claim 1, wherein the second pipe is wound in a helical shape along an outer surface of the first pipe to pass between gas outlets of the first pipe.

8. The gas supply pipe of claim 1, wherein the second pipe is wound in a helical shape along an inner surface of the first pipe to pass between gas outlets of the first pipe.

9. The gas supply pipe of claim 1, wherein the cooling medium includes at least one selected from the group consisting of helium (He) gas, argon (Ar) gas, nitride (N2) gas, inert gas, cooling water, and cooling oil, or a combination thereof.

10. A chemical vapor deposition (CVD) apparatus comprising:
a reacting furnace sized and configured to accommodate at least one wafer loaded on a boat;
a gas supply pipe comprising a first pipe connected to a gas storage apparatus via a gas supply line to supply a reacting gas into the reacting furnace, and a second pipe thermally contacting the first pipe to cool the first pipe, wherein a first end of the second pipe is connected to a cooling medium supplying unit via a cooling medium line such that a cooling medium circulates inside the second pipe, and wherein a second, opposite end of the second pipe is connected to a cooling medium collecting unit;
a temperature sensor configured to measure a temperature of the first pipe; and
a controller configured to receive a temperature signal indicating a temperature from the temperature sensor and configured to apply a control signal to the cooling medium supplying unit and/or the cooling medium collecting unit responsive to the received temperature signal.

11. The CVD apparatus of claim 10, wherein the controller is configured to apply a cooling stop signal to the cooling medium supplying unit and/or the cooling medium collecting unit when the temperature signal indicates a temperature lower than a first temperature, and wherein the controller is configured to apply a cooling operation signal to the cooling medium supplying unit and/or the cooling medium collecting unit when the temperature signal indicates a temperature greater than a second temperature.

12. The CVD apparatus of claim 11, wherein the first temperature is about 400° C. and wherein the second temperature is about 500° C.

13. A chemical vapor deposition (CVD) apparatus comprising:
a reacting furnace sized and configured to accommodate at least one wafer loaded on a boat;
a gas supply pipe comprising a first pipe connected to a gas storage apparatus via a gas supply line, the first pipe having a plurality of gas outlets to supply gas from the first pipe to the reacting furnace, the gas supply pipe further comprising a second pipe thermally contacting the first pipe to cool the first pipe, wherein a first end of the second pipe is connected to a cooling medium supplying unit via a cooling medium line such that a cooling medium circulates inside the second pipe, and wherein a second, opposite end of the second pipe is connected to a cooling medium collecting unit;
a temperature sensor configured to measure a temperature of at least one of the first pipe and reacting gas within the first pipe; and
a controller configured to receive a temperature signal indicating a temperature from the temperature sensor and configured to apply a control signal to at least one of the cooling medium supplying unit and the cooling medium collecting unit responsive to the received temperature signal.

14. The CVD apparatus of claim 13, wherein the second pipe is installed outside of the first pipe and extends along diametrically opposed first and second side surfaces of the first pipe.

15. The CVD apparatus of claim 14, wherein the first pipe is a cylindrical pipe, and wherein the second pipe is formed to have a crescent-shaped cross-section to closely contact the first pipe.

16. The CVD apparatus of claim 13, wherein the second pipe is installed inside of the first pipe.

17. The CVD apparatus of claim 13, wherein the second pipe is wound in a helical shape along an outer surface of the first pipe to pass between the gas outlets of the first pipe.

18. The CVD apparatus of claim 13, wherein the second pipe is wound in a helical shape along an inner surface of the first pipe to pass between gas outlets of the first pipe.

19. The CVD apparatus of claim 13, wherein the controller is configured to apply a cooling stop signal to at least one of the cooling medium supplying unit and the cooling medium collecting unit when the temperature signal indicates a temperature lower than a first temperature, and wherein the controller is configured to apply a cooling operation signal to at least one of the cooling medium supplying unit and the cooling medium collecting unit when the temperature signal indicates a temperature greater than a second temperature.

20. The CVD apparatus of claim 19, wherein the first temperature is about 400° C. and wherein the second temperature is about 500° C.
